(19) United States
(12) Patent Application Publication
(10) Pub. No.: US 2022/0209153 A1
(43) Pub. Date: Jun. 30, 2022

(54) WHITE LIGHT EMITTING DEVICE AND LIGHT EMITTING DISPLAY DEVICE INCLUDING THE SAME

(71) Applicant: LG DISPLAY CO., LTD., SEOUL (KR)

(72) Inventors: Yong Hwan KIM, SEOUL (KR); Ki Woog SONG, Seoul (KR)

(73) Assignee: LG DISPLAY CO., LTD., SEOUL (KR)

(21) Appl. No.: 17/549,323

(22) Filed: Dec. 13, 2021

(30) Foreign Application Priority Data
Dec. 29, 2020 (KR) 10-2020-0186847

(51) Int. Cl. H01L 51/50; H01L 27/32

(52) U.S. Cl. CPC H01L 51/504; H01L 51/5072; H01L 27/3218; H01L 51/5056

(57) ABSTRACT

A white light emitting device and the light emitting display device including the same have an improved structure capable of preventing a color difference between regions and eliminating a difference in color characteristics between a low grayscale level and a high grayscale level.

### CROSS-REFERENCE TO RELATED APPLICATION

This application claims the priority of Korean Patent Application No. 10-2020-0186847, filed on Dec. 29, 2020, which is hereby incorporated by reference in its entirety as if fully set forth herein.

### BACKGROUND

### Field of the Disclosure

The present disclosure relates to a display device, and more particularly to a white light emitting device and a light emitting display device including the same. Although the present disclosure is suitable for a wide scope of applications, it is particularly suitable for preventing a color difference between regions and eliminating a difference in color characteristics between a low grayscale level and a high grayscale level.

### Description of the Background

A self-emission display device has been considered a competitive application because it does not require a separate light source and enables implementation of a compact device design and vivid color display. The self-emission display device may be classified into an organic light emitting display device and an inorganic light emitting display device depending on the light emitting material therein.

A self-emission display device includes a plurality of subpixels and a light emitting device provided in each of the subpixels, thereby emitting light without a separate light source.

As a tandem device like a display device, which can achieve high resolution and high integration and in which an organic layer and an emission layer are commonly formed without a fine metal mask, has recently received increased attention due to the advantageous processability thereof, and research thereon is underway.

A light emitting display device generally requires the ability to express various colors with high efficiency, and is generally formed of a plurality of emission layers in a stack structure.

However, there is a difference in efficiency between emission layers of different colors. Further, when a plurality of emission layers is driven at a low current density and a high current density, the emission layers may nonuniformly emit colors, which may be considered color abnormality.

### SUMMARY

Accordingly, the present disclosure to provide a white light emitting device and a light emitting display device including the same, which have an improved structure capable of preventing a color difference between regions and eliminating a difference in color characteristics between a low grayscale level and a high grayscale level.

A white light emitting device according to an aspect of the present disclosure may include a first electrode and a second electrode disposed opposite each other on a substrate, a first stack disposed between the first electrode and a first charge generation layer, the first stack being configured to emit first light, and a second stack disposed between the first charge generation layer and the second electrode, the second stack including first to third emission layers stacked one on another. The first to third emission layers may emit lights such that the wavelengths of the lights are gradually shortened in a direction moving away from the first stack, and the thicknesses of the first to third emission layers may be gradually reduced in the order of the second emission layer, the first emission layer, and the third emission layer.

A light emitting display device according to an aspect of the present disclosure may include a substrate including a plurality of subpixels, a first electrode provided in each of the plurality of subpixels on the substrate, a second electrode provided over the plurality of subpixels so as to be opposite the first electrode, a first stack disposed between the first electrode and a first charge generation layer over the plurality of subpixels, the first stack being configured to emit first light, and a second stack disposed between the first charge generation layer and the second electrode over the plurality of subpixels, the second stack including first to third emission layers stacked one on another. The first to third emission layers may emit lights such that the wavelengths of the lights are gradually shortened in a direction moving away from the first stack, and the thicknesses of the first to third emission layers may be gradually reduced in the order of the second emission layer, the first emission layer, and the third emission layer.

### BRIEF DESCRIPTION OF THE DRAWINGS

The accompanying drawings, which are included to provide a further understanding of the disclosure and are incorporated in and constitute a part of the disclosure, illustrate aspect(s) of the disclosure and together with the description serve to explain the principle of the disclosure.

In the drawings:

FIG. 1 is a cross-sectional view showing a white light emitting device according to a first aspect of the present disclosure;

FIG. 2 is a cross-sectional view showing a white light emitting device according to a second aspect of the present disclosure;

FIG. 3 is a diagram showing a second stack of the white light emitting device of the present disclosure;

FIGS. 4A to 4D are graphs showing the relationship between current density and a CIEy color coordinate in first to fourth experimental examples;

FIGS. 5A and 5B are graphs showing the relationship between current density and the CIEy color coordinate in fourth and fifth experimental examples;

FIG. 6 is a plan view showing a light emitting display device of the present disclosure;

FIG. 7 is a diagram showing a change in the thickness of a third emission layer along line I-I′ in FIG. 6;

FIG. 8 is a cross-sectional view showing the light emitting display device according to the present disclosure in connection with a lower driving unit; and

FIG. 9 is a circuit diagram of a subpixel according to an example of the light emitting display device of the present disclosure.

### DETAILED DESCRIPTION

Reference will now be made in detail to exemplary aspects of the present disclosure, examples of which are illustrated in the accompanying drawings. Wherever possible, the same reference numbers will be used throughout the drawings to refer to the same or like parts. In the following description of the present disclosure, a detailed description of known functions and configurations incorporated herein will be omitted when it may obscure the subject matter of the present disclosure. In addition, in the following description of the present disclosure, the names of the elements are selected for ease of explanation, and may be different from actual names.

In the drawings for explaining the exemplary aspects of the present disclosure, for example, the illustrated shape, size, ratio, angle, and number are given by way of example, and thus, are not limited to the disclosure of the present disclosure. Throughout the present specification, the same reference numerals designate the same constituent elements. In addition, in the following description of the present disclosure, a detailed description of known functions and configurations incorporated herein will be omitted when it may make the subject matter of the present disclosure rather unclear. The terms “comprises,” “includes,” and/or “has”, used in this specification, do not preclude the presence or addition of other elements unless used along with the term “only”. The singular forms are intended to include the plural forms as well, unless the context clearly indicates otherwise.

In the interpretation of constituent elements included in the various aspects of the present disclosure, the constituent elements are interpreted as including an error range even if there is no explicit description thereof.

In the description of the various aspects of the present disclosure, when describing positional relationships, for example, when the positional relationship between two parts is described using “on”, “above”, “below”, “next to”, or the like, one or more other parts may be located between the two parts unless the term “directly” or “closely” is used.

In the description of the various aspects of the present disclosure, when describing temporal relationships, for example, when the temporal relationship between two actions is described using “after”, “subsequently”, “next”, “before”, or the like, the actions may not occur in succession unless the term “directly” or “just” is used therewith.

In the description of the various aspects of the present disclosure, although terms such as, for example, “first” and “second” may be used to describe various elements, these terms are merely used to distinguish the same or similar elements from each other. Therefore, in the present specification, an element indicated by “first” may be the same as an element indicated by “second” without exceeding the technical scope of the present disclosure, unless otherwise mentioned.

The respective features of the various aspects of the present disclosure may be partially or wholly coupled to and combined with each other, and various technical linkages and modes of operation thereof are possible. These various aspects may be performed independently of each other, or may be performed in association with each other.

In this specification, the term “doped” means that a material of any layer having physical properties (e.g., N-type and P-type, or an organic material and an inorganic material) different from the material that occupies the greatest weight percentage of the corresponding layer is added to the material accounting for the greatest weight percentage in an amount corresponding to a weight percentage of 30 vol % or less. In other words, a “doped” layer means a layer in which a host material and a dopant material of any layer are distinguishable from each other in consideration of the weight percentages thereof. In addition, the term “undoped” refers to all cases excluding the case that corresponds to the term “doped”. For example, when any layer is formed of a single material or is formed of a mixture of materials having the same or similar properties, the layer is considered an “undoped” layer. In another example, when at least one of constituent materials of any layer is of a P-type and all of the other constituent materials of the layer are not of an N-type, the layer is considered an “undoped” layer. In another example, when at least one of the constituent materials of any layer is an organic material and all of the other constituent materials of the layer are not an inorganic material, the layer is considered an “undoped” layer. In another example, when all constituent materials of any layer are organic materials, at least one of the constituent materials is of an N-type, at least another constituent material is of a P-type, and the weight percent of the N-type material is 30 vol % or less or the weight percent of the P-type material is 30 vol % or less, the layer is considered a “doped” layer.

In this specification, an electroluminescence (EL) spectrum is calculated by multiplying (1) a photoluminescence (PL) spectrum, which applies the inherent characteristics of an emissive material such as a dopant material or a host material included in an organic emission layer, by (2) an outcoupling or emittance spectrum curve, which is determined by the structure and optical characteristics of an organic light-emitting element including the thicknesses of organic layers such as, for example, an electron transport layer.

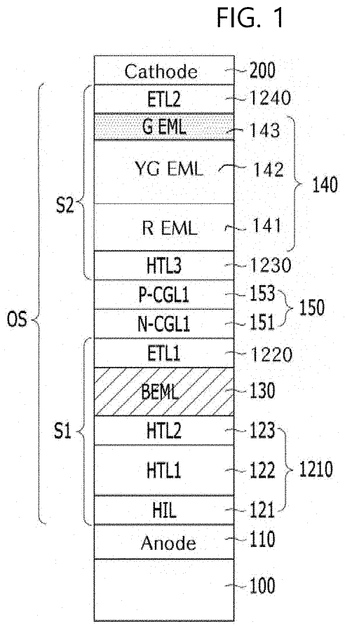

FIG. 1 is a cross-sectional view showing a white light emitting device according to a first aspect of the present disclosure.

As shown in FIG. 1, a white light emitting device according to a first aspect of the present disclosure includes a first electrode 110 and a second electrode 200, which are disposed to be opposite each other over a substrate 100, and further includes a charge generation layer 150 disposed between the first electrode 110 and the second electrode 200, a first stack S1 disposed between the first electrode 110 and the charge generation layer 150, and a second stack S2 disposed between the second electrode 200 and the charge generation layer 150.

The first stack S1 is located on the first electrode 110, and includes a first hole-transport-related common layer 1210, a blue emission layer 130, and a first electron-transport-related common layer 1220.

The second stack S2 includes a second hole-transport-related common layer 1230, first to third emission layers 141, 142 and 143, which are sequentially stacked and emit lights, the wavelengths of which are gradually shortened from the first emission layer 141 to the third emission layer 143, and a second electron-transport-related common layer 1240.

Each of the first and second hole-transport-related common layers 1210 and 1230 is a layer related to hole injection and hole transport, and may include at least one of a hole transport layer HTL1, HTL2 or HTL3 or an electron-blocking layer. In addition, the first hole-transport-related common layer 1210 may further include a hole injection layer HIL (121), which is in contact with the first electrode 110 and lowers interfacial resistance when holes are injected from the first electrode 110. Each of the first and second hole-transport-related common layers 1210 and 1230 may be formed as a single layer, or may be formed as multiple layers. As illustrated, the hole-transport-related common layer included in one of the stacks may be formed as multiple layers, and the hole-transport-related common layer included in the other one of the stacks may be formed as a single layer. For example, as shown in FIG. 1, when the first hole-transport-related common layer 1210 of the first stack S1 is formed as multiple layers, the hole transport layer HTL2, which is close to the emission layer 130, may function as an electron-blocking layer that prevents electrons or excitons from escaping from the emission layer 130 to the hole transport layer 122.

Each of the first and second electron-transport-related common layers 1220 and 1240 is a layer related to the transport of electrons and the rate of supply of electrons to an adjacent emission layer, and may include at least one of an electron transport layer ETL1 or ETL2 or a hole-blocking layer. In addition, the second electron-transport-related common layer 1240 may further include an electron injection layer, which is in contact with the second electrode 200 and lowers interfacial resistance when electrons are injected from the second electrode 200. Each of the first and second electron-transport-related common layers 1220 and 1240 may be formed as a single layer, or may be formed as multiple layers.

In the white light emitting device according to the first aspect of the present disclosure, the first stack S1 includes a single blue emission layer 130 to emit blue light. The blue light may have an emission peak within the range from 430 nm to 490 nm.

Unlike the first stack S1, the second stack S2 includes a phosphorescent emission unit 140, which is configured such that first to third emission layers 141, 142 and 143 are in contact with each other and emit different lights of longer wavelengths than the wavelength of blue light. Specifically, the first to third emission layers 141, 142 and 143 respectively emit red light, yellowish-green light, and green light. That is, the first emission layer 141 emits light having an emission peak within the range from 590 nm to 650 nm, the second emission layer 142 emits light having an emission peak within the range from 540 nm to 590 nm, and the third emission layer 143 emits light having an emission peak within the range from 510 nm to 560 nm. Among the first to third emission layers 141, 142 and 143 of the second stack S2, the third emission layer 143 emits light of the shortest wavelength. However, the light from the third emission layer 143 has a longer wavelength than the light from the blue emission layer 130.

The reason why the first to third emission layers 141, 142 and 143, which emit lights of different wavelengths, are provided in the second stack S2 is to enable rich color representation by the light emitting display device. As long as each of the emission layers for emitting lights of various colors does not impair the emission characteristics of other emission layers, as the number of emission layers increases, a color representation effect may be improved, and the color representation range achievable by the light emitting display device may be increased. This means that a great deal of the color representation range achievable by the light emitting display device falls within the range according to the DCI standard or the BT2020 standard.

The emission layers of the second stack S2, which emit lights of long wavelengths, may be implemented as highly efficient phosphorescent emission layers. Because the threshold drive voltage is gradually reduced in the order of the third emission layer 143, the second emission layer 142, and the first emission layer 141, energy not used for excitation in the upper emission layer in the second stack S2 may be used in the lower emission layer. Accordingly, it is possible to increase the efficiency of the second stack S2. To this end, the first to third emission layers 141, 142 and 143 are formed such that the wavelengths of the lights emitted therefrom are gradually increased in the order of the third emission layer 143, the second emission layer 142, and the first emission layer 141 so that the threshold drive voltage is gradually reduced in that order. In the aspect shown in FIG. 1, the first emission layer 141 is a red emission layer, the second emission layer 142 is a yellowish-green emission layer, and the third emission layer 143 is a green emission layer.

In the white light emitting device of the present disclosure, in which multiple emission layers are disposed adjacent to each other, the emission layers 141, 142 and 143 have a thickness difference therebetween in the second stack S2. Among the emission layers of the second stack S2, the second emission layer 142 has the largest thickness, and the third emission layer 143 has the smallest thickness. That is, the emission layers 140, which emit phosphorescent light, have the following thickness relationship therebetween: thickness of second emission layer 142>thickness of first emission layer 141>thickness of third emission layer 143. Here, since the second emission layer 142, which expresses a white color, accounts for the greatest portion, the second emission layer 142 may be the thickest layer in the second stack S2, and the first emission layer 141 and the third emission layer 143 may be thinner than the second emission layer 142. The reason why the third emission layer 143 is thinner than the first emission layer 141 is to minimize or prevent the occurrence of color abnormality in the edge region of the substrate 100, which may occur at a low current density, by thinning the third emission layer 143, which is formed relatively late in a deposition process and thus is sensitive to thermal stress.

In the white light emitting device of the present disclosure, the organic stack OS, which includes the first stack S1 disposed on the first electrode 110, the charge generation layer 150, and the second stack S2, and the second electrode 200 are layers that are formed continuously in the display area of the substrate 100 without breaks therein. That is, when a plurality of subpixels is provided on the substrate 100, the first electrode 110 is divided for each subpixel, but each of the components disposed thereon is formed in a unitary body in at least the display area, without using a fine metal mask. Accordingly, in the white light emitting device of the present disclosure, the use of a fine metal mask may be omitted after the formation of the first electrode 110, whereby it is possible to improve processability and to alleviate a decrease in yield that may be caused by misalignment of masks. In addition, in the white light emitting device of the present disclosure, lights of different colors emitted from the multiple stacks S1 and S2 may be combined to generate white light, and the subpixels may emit lights of different colors to color filters 109R, 109G and 109B (shown in FIG. 8), which are provided at emission sides of respective subpixels. Each of the layers of the organic stack OS of the white light emitting device of the present disclosure may be formed using an open mask that completely opens the display area of the substrate 100.

Each of the layers of the first stack S1, the charge generation layer 150, the layers of the second stack S2, and the second electrode 200 is formed in a unitary body in the display area by supplying a vaporized material from a source to a deposition chamber. In this case, in the process of depositing each layer, a difference in thermal gradient may occur between the central region and the edge region of the display area of the substrate 100, and an entropy difference may occur between portions of the deposition surface of each layer.

Further, an organic material is deposited on respective layers at different temperatures. In particular, the emission layers of the second stack are continuously formed, and heat is continuously applied to the substrate 100 while the emission layers are stacked upwards. Therefore, during the deposition of the third emission layer 143, which is the last deposition layer of the emission layers, a difference in thermal gradient between regions of the substrate 100 may increase, thus leading to a larger difference in thickness between the central region and the edge region of the third emission layer. In the aspect shown in FIG. 1, the overall thickness of the third emission layer 143 of the second stack S2 is reduced, whereby the third emission layer 143 is less affected by a difference in thermal gradient between regions of the substrate 100.

Hereinafter, the thickness relationship between the emission layers in the phosphorescent emission unit 140 and resultant effects will be described in detail.

Each of the blue emission layer 130 and the first to third emission layers 141, 142 and 143 includes a host and a dopant. One or multiple hosts may be provided in each emission layer as needed.

The blue emission layer 130 includes a fluorescent dopant, and each of the first to third emission layers 141, 142 and 143 includes a phosphorescent dopant, which has relatively high efficiency. The phosphorescent dopant of each of the first to third emission layers 141, 142 and 143 is a metal complex compound including one of iridium (Ir), platinum (Pt), osmium (Os), gold (Au), titanium (Ti), zirconium (Zr), hafnium (Hf), europium (Eu), terbium (Tb), palladium (Pd), and thulium (Tm). The host of each of the first to third emission layers 141, 142 and 143 may include a host having electron transport capability and/or a host having hole transport capability. The phosphorescent dopants of the first to third emission layers 141, 142 and 143 have a difference in triplet level T1 required for excitation.

As illustrated, the charge generation layer 150 located between the stacks S1 and S2 may include an n-type charge generation layer 151 and a p-type charge generation layer 153. Alternatively, the charge generation layer 150 may be formed as a single layer in which an n-type dopant and a p-type dopant are included in a single host.

The first electrode 110 may function as an anode, and the second electrode 200 may function as a cathode. The first electrode 110 may include a transparent electrode, and the second electrode 200 may include a reflective electrode.

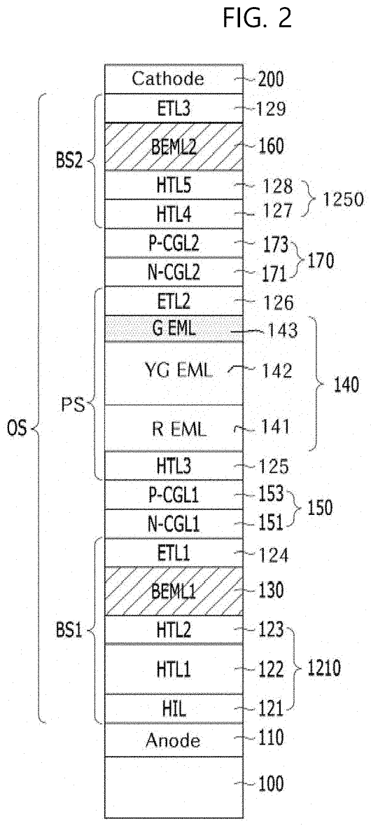

FIG. 2 is a cross-sectional view showing a white light emitting device according to a second aspect of the present disclosure.

As shown in FIG. 2, the white light emitting device according to the second aspect of the present disclosure includes a phosphorescent stack PS, which includes first to third emission layers 141, 142 and 143, a first blue emission stack BS1, which is located under the phosphorescent stack PS and emits blue light, and a second blue emission stack BS2, which is located on the phosphorescent stack PS and emits blue light. That is, the white light emitting device according to the second aspect differs from the first aspect in that multiple blue emission stacks are provided in order to increase the efficiency of blue color emission, which is insufficient compared to the phosphorescent stack PS.

In addition, a charge generation layer 150 is provided between the first blue emission stack BS1 and the phosphorescent stack PS, and a charge generation layer 170 is provided between the second blue emission stack BS2 and the phosphorescent stack PS. As illustrated, the charge generation layer 150 may include an n-type charge generation layer 151 and a p-type charge generation layer 153 stacked on the n-type charge generation layer 151, and the charge generation layer 170 may include an n-type charge generation layer 171 and a p-type charge generation layer 173 stacked on the n-type charge generation layer 171. Alternatively, each of the charge generation layers 150 and 170 may be formed as a single layer in which an n-type dopant and a p-type dopant are included in a single host.

Although a single subpixel is illustrated in FIG. 2, the first electrode 110 may be patterned corresponding to a plurality of subpixels so as to be divided for each subpixel. The organic stack OS, which is located on the first electrode 110, and the second electrode 200 may be formed continuously over the plurality of subpixels without breaks therein.

In the white light emitting device according to the second aspect of the present disclosure, the first electrode 110 is divided for each subpixel, but each of the components disposed thereon is formed in a unitary body in at least the display area, without using a fine metal mask. Accordingly, in the white light emitting device according to the second aspect of the present disclosure, the use of a fine metal mask may be omitted after the formation of the first electrode 110, whereby it is possible to improve processability and to alleviate a decrease in yield that may be caused by misalignment of masks. In addition, in the white light emitting device according to the second aspect of the present disclosure, lights of different colors emitted from the multiple stacks S1 and S2 (or blue stacks BS1 and BS2) and a phosphorescent stack PS) may be combined to generate white light, and the subpixels may emit lights of different colors to color filters 109R, 109G and 109B (shown in FIG. 8), which are provided at emission sides of respective subpixels.

The first blue emission stack B S1 is located on the first electrode 110, and includes a first hole-transport-related common layer 1210, a first blue emission layer BEML1 (130), and a first electron-transport-related common layer 124.

The second stack S2 (phosphorescent stack) includes a second hole-transport-related common layer 125, first to third emission layers 141, 142 and 143, which are sequentially stacked and emit lights, the wavelengths of which are gradually shortened from the first emission layer 141 to the third emission layer 143, and a second electron-transport-related common layer 126.

The second blue emission stack BS2 includes a third hole-transport-related common layer 1250, a second blue emission layer BEML2 (160), and a third electron-transport-related common layer 129.

Similar to the first blue emission stack BS1, the third hole-transport-related common layer 1250 may include a plurality of hole transport layers 127 and 128. The hole transport layer HTL5 (128), which is located on the hole transport layer HTL4 (127), may function as an electron-blocking layer.

The first electrode 110 may include a transparent electrode, and the second electrode 200 may include a reflective electrode, so the light generated by the organic stack OS may be emitted through the first electrode 110.

The second electrode 200 may be formed such that multiple layers are stacked one on another. Among the multiple layers, the layer that is in contact with the organic stack OS may be formed of an inorganic compound including metal and a halogen material such as fluorine, and may function as an electron injection layer. When an electron injection layer is formed of an inorganic material or an inorganic compound, the electron injection layer may be formed in a different chamber from the organic stack OS, and may be formed using the same mask and/or in the same chamber as the second electrode 200.

As described above, each of the first and second aspects includes the phosphorescent stack S2 or PS having the phosphorescent unit 140, in which multiple phosphorescent emission layers are sequentially stacked. The light emitting principle of the phosphorescent stack PS will now be described in brief.

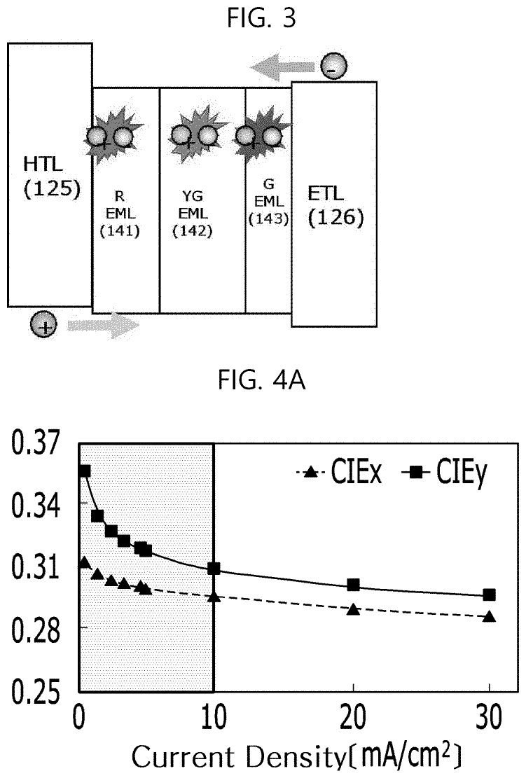

FIG. 3 is a diagram showing the second stack of the white light emitting device of the present disclosure.

As shown in FIG. 3, holes are supplied to the phosphorescent unit 140 from the second hole-transport-related common layer 125 in the second stack S2, and electrons are supplied to the phosphorescent unit 140 from the second electron-transport-related common layer 126 in the second stack S2. Excitons are generated by recombination of the holes and the electrons in each of the first to third emission layers 141, 142 and 143, and light emission occurs when the energy of the excitons falls to a ground state.

The first to third emission layers 141, 142 and 143 are disposed between the second hole- transport-related common layer 125 and the second electron-transport-related common layer 126, and emit lights, the wavelengths of which are gradually shortened in a direction approaching the second electron-transport-related common layer 126. The thicknesses of the first to third emission layers 141, 142 and 143 are gradually reduced in the order of the second emission layer 142, the first emission layer 141, and the third emission layer 143.

Among the emission layers of the second stack S2, the second emission layer 142 has the largest thickness, and the third emission layer 143 has the smallest thickness. That is, the emission layers 140, which emit phosphorescent light, have the following thickness relationship: thickness of second emission layer 142>thickness of first emission layer 141>thickness of third emission layer 143. Here, since the second emission layer 142, which expresses a white color, accounts for the greatest portion, the second emission layer 142 may be the thickest layer in the second stack S2, and the first emission layer 141 and the third emission layer 143 may be thinner than the second emission layer 142. The reason why the third emission layer 143 is thinner than the first emission layer 141 is to minimize or prevent the occurrence of color abnormality in the edge region of the substrate 100, which may occur at a low current density, by thinning the third emission layer 143, which is formed relatively late in a deposition process and thus is sensitive to thermal stress.

The total thickness of the phosphorescent emission unit 140, which includes the first to third emission layers 141, 142 and 143, may be 350 Å to 450 Å. Since a total of three emission layers are provided in the phosphorescent emission unit 140, the first to third emission layers 141, 142 and 143 are formed to have appropriate respective thicknesses taking into consideration the total thickness of the phosphorescent emission unit 140. The emission layers of the phosphorescent emission unit 140 are formed of a highly efficient phosphorescent emission material, and are arranged such that the wavelengths of the lights emitted therefrom are gradually increased in the order of the third emission layer 143, the second emission layer 142, and the first emission layer 141. Here, the first emission layer 141 emits red light, the second emission layer 142 emits yellowish-green light, and the third emission layer 143 emits green light.

The third emission layer 143 may be the thinnest layer in the phosphorescent emission unit 140, and the thickness of the third emission layer 143 may be 20% to 30% of the total thickness of the phosphorescent emission unit 140. The thickness of the third emission layer 143 may be smaller than the thickness of the first emission layer or the second emission layer.

In the white light emitting device of the present disclosure, the reason why the third emission layer 143 has the smallest thickness is that variation in color coordinates of the third emission layer 143, which emits green light, due to variation in current density is greater than that of the first emission layer 141, which emits red light, or the second emission layer 142, which emits yellowish-green light.

Hereinafter, variation in color coordinates of experimental examples due to variation in current density will be described. In particular, the color coordinates greatly change at a low current density. Hereinafter, the result of observation of variation in color coordinates within the low current density range from 0.25 mA/cm² to 10 mA/cm² will be described.

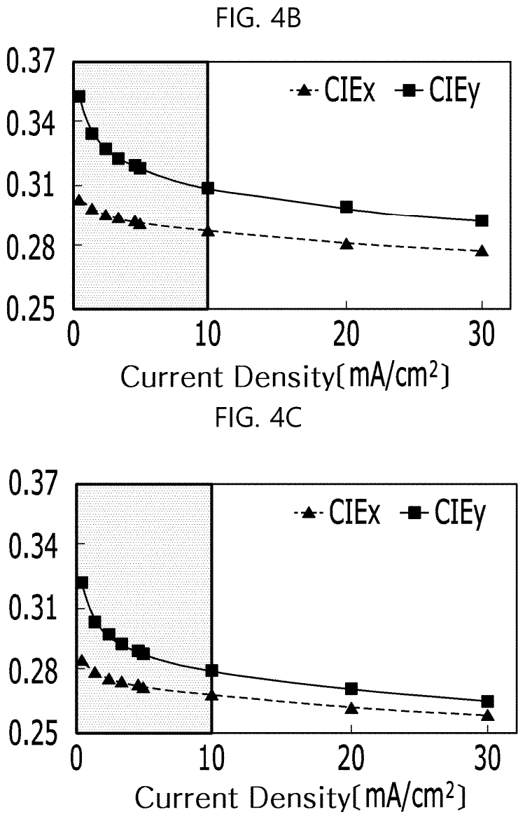

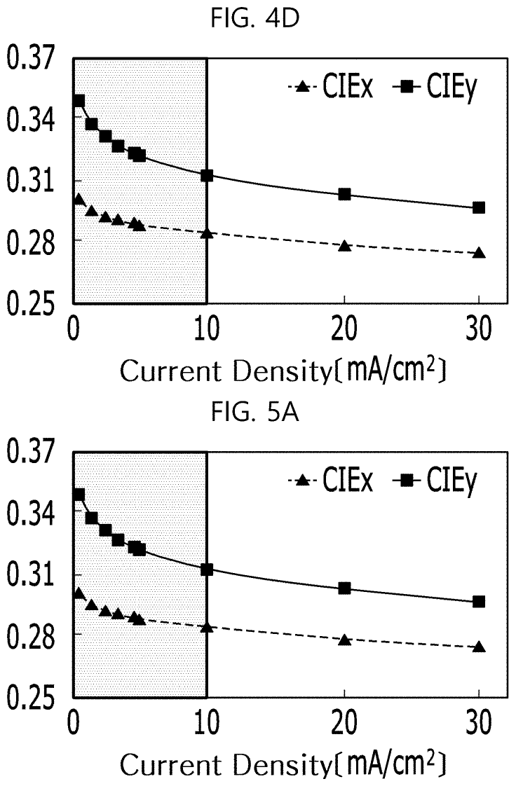

FIGS. 4A to 4D are graphs showing the relationship between current density and a CIEy color coordinate in first to fourth experimental examples.

TABLE 1

| Thickness Ratio | Ex1 | Ex2 | Ex3 | Ex4 |
|---|---|---|---|---|
| (141:142:143) | (0.75:1:1) | (0.75:1:0.55) | (0.75:1:0.5) | (0.75:1:0.45) |
| ΔCIEx at Low | 0.019 | 0.016 | 0.016 | 0.017 |
| current Density | | | | |
| ΔCIEy at Low | 0.048 | 0.045 | 0.043 | 0.037 |
| current Density | | | | |
| Edge Gray Level | 4 | 4 | 2 | 1 |
| (Determined at 32 | | | | |
| Gray Levels) | | | | |
| Color | Abnormal | Abnormal | Normal | Normal |

Each of the first to fourth experimental examples Ex1, Ex2, Ex3 and Ex4 has the structure of the white light emitting device shown in FIG. 2. However, the first to fourth experimental examples Ex1, Ex2, Ex3 and Ex4 have different respective thickness ratios of the first to third emission layers 141, 142 and 143. Specifically, in each of the first to fourth experimental examples Ex1, Ex2, Ex3 and Ex4, the second emission layer 142 has the largest thickness, and the thickness of the first emission layer 141 is 0.75 times the thickness of the second emission layer 142. In the first experimental example Ex1, the thickness of the third emission layer 143 is the same as the thickness of the second emission layer 142. In the second experimental example Ex2, the thickness of the third emission layer 143 is 0.55 times the thickness of the second emission layer 142. In the third experimental example Ex3, the thickness of the third emission layer 143 is 0.5 times the thickness of the second emission layer 142. In the fourth experimental example Ex4, the thickness of the third emission layer 143 is 0.45 times the thickness of the second emission layer 142. Under the conditions of the above-described thickness ratios of the first to third emission layers 141, 142 and 143, a white color was realized at a low current density, variation in the CIEx color coordinate ΔCIEx, variation in the CIEy color coordinate ΔCIEy, and an edge gray level value were measured, and a determination as to the abnormality or normality of color was made. In each of the first to fourth experimental examples Ex1, Ex2, Ex3 and Ex4, variation in the CIEx color coordinate ΔCIEx was small, specifically 0.020 or less, and variation in the CIEy color coordinate ΔCIEy was larger than variation in the CIEx color coordinate ΔCIEx. In particular, as shown in FIGS. 4A and 4B, in each of the first and second experimental examples Ex1 and Ex2, there was a large difference between variation in the CIEy color coordinate ΔCIEy at a high current density (more than 10 mA/cm²) and variation in the CIEy color coordinate ΔCIEy at a low current density (0.25 mA/cm² to 10 mA/cm²), and, when driven at a low current density, at which the CIEy color coordinate greatly changes, a green color was expressed more strongly than when a white color was realized at a high current density. However, it can be seen that variation in the CIEy color coordinate ΔCIEy in the second experimental example Ex2 when driven at a low current density and a high current density was smaller than that in the first experimental example Ex1.

In addition, it can be seen from Table 1 that, as the thickness of the third emission layer 143 is reduced from the first experimental example Ex1 to the fourth experimental example Ex4, variation in the CIEy color coordinate ΔCIEy at a low current density is reduced, and the degree of variation in the CIEy color coordinate at a low current density and the degree of variation in the CIEy color coordinate at a high current density become more similar to each other.

The edge gray level shown in Table 1 is a value determined at 32 gray levels. The larger the value of the edge gray level, the greater the degree of deviation from a normal range. Further, the abnormality or normality of color is determined based on variation in the CIEy color coordinate ΔCIEy and the value of the edge gray level. The value of the edge gray level indicates a difference in color characteristics between the edge region and the central region of the display area of the substrate when driven at a low current density.

It can be seen from Table 1 that, when driven at a low current density, color abnormality occurred in the first experimental example Ex1 and the second experimental example Ex2, whereas color abnormality was eliminated in the third experimental example Ex3 and the fourth experimental example Ex4.

In addition, it can be seen that variation in the CIEy color coordinate ΔCIEy gradually decreases from the first experimental example Ex1 to the fourth experimental example Ex4. Accordingly, it can be expected that the white light emitting device of the present disclosure having the phosphorescent emission unit 140 structured as shown in FIG. 3 exhibits an improved effect when the thickness of the third emission layer 143 is greater than or equal to 45% and less than 55% of the thickness of the second emission layer 142.

Hereinafter, the result of observation of color representation and variation in color coordinates due to variation in current density when driven at a low current density under the condition that the thickness of the first emission layer varies while the thickness relationship between the second and third emission layers is fixed will be described.

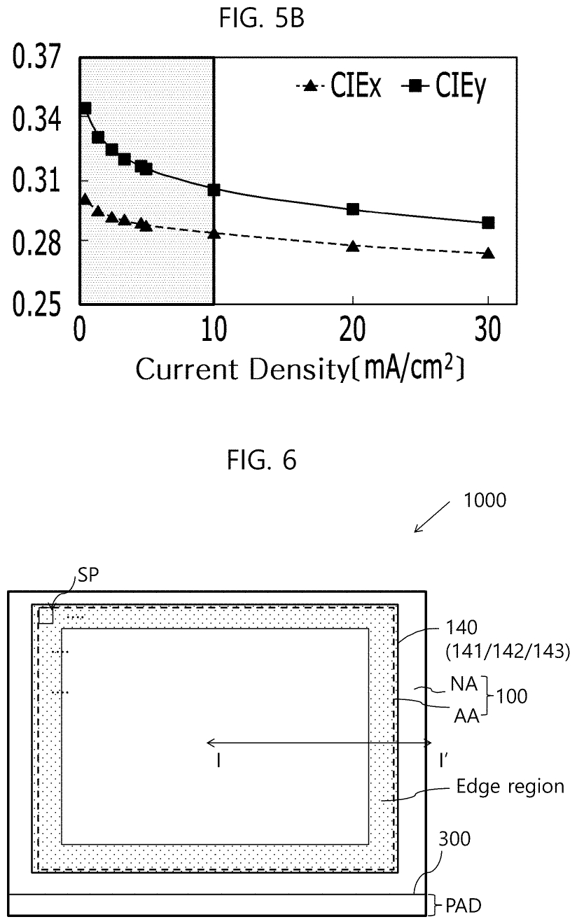

FIGS. 5A and 5B are graphs showing the relationship between current density and the CIEy color coordinate in fourth and fifth experimental examples.

TABLE 2

| Thickness Ratio | Ex4 | Ex5 |
|---|---|---|
| (141:142:143) | (0.75:1:0.45) | (0.65:1:0.45) |
| ΔCIEx at Low current Density | 0.017 | 0.018 |
| ΔCIEy at Low current Density | 0.037 | 0.039 |
| Edge Gray Level | 1 | 1 |
| (Determined at 32 Gray Levels) | | |
| Color | Normal | Normal |

As shown in Table 2, the thickness of the third emission layer was fixed at 0.45 times the thickness of the second emission layer. In the fourth experimental example Ex4, variation in the CIEy color coordinate ΔCIEy at a low current density (0.25 mA/cm² to 10 mA/cm²) was measured to be 0.037, and the gray level at the edge region of the display area of the substrate was measured to be 1. In the fifth experimental example Ex5, variation in the CIEy color coordinate ΔCIEy at a low current density (0.25 mA/cm² to 10 mA/cm²) was measured to be 0.039, and the gray level at the edge region of the display area of the substrate was measured to be 1. Further, no color abnormality occurred in the fourth and fifth experimental examples Ex4 and Ex5. That is, it can be expected that, when the thickness of the first emission layer ranges from 0.65 times to 0.75 times the thickness of the second emission layer, no color abnormality occurs when driven at a low current density.

It can be seen from the above experiment results that the thickness of the first emission layer 141 may be in the range from 29.5% (0.65/(0.65+1+0.55)) to 34.1% (0.75/(0.75+1+0.45)) of the total thickness of the first to third emission layers.

Meanwhile, the thickness of the third emission layer 143 is set to 20% to 30% of the total thickness of the first to third emission layers. The reason why the thickness range of the third emission layer 143 is relatively large is as follows.

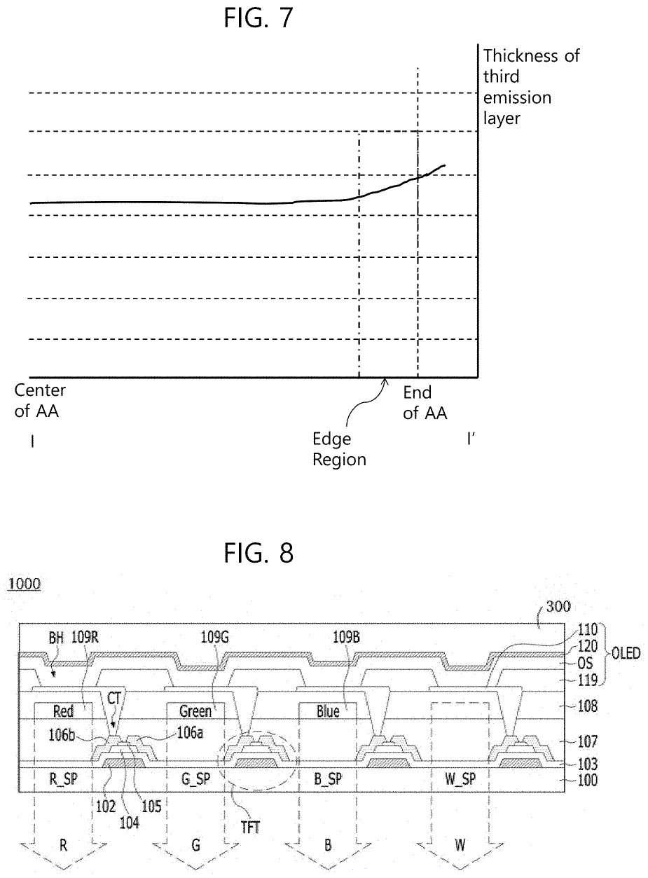

FIG. 6 is a plan view showing a light emitting display device of the present disclosure, and FIG. 7 is a diagram showing a change in the thickness of the third emission layer along line I-I′ in FIG. 6.

As shown in FIG. 6, a light emitting display device of the present disclosure may include a substrate 100, and the substrate 100 may include a display area AA, which has a plurality of subpixels SP, and a non-display area NA, which is formed around the display area AA and in which a pad unit PAD, link lines connecting lines of the display area AA to the pad unit PAD, a ground line, and power voltage lines are disposed.

In the light emitting display device of the present disclosure, the layers of the organic stack OS and the second electrode 200 shown in FIGS. 1 and 2 occupy the entire region of the display area AA and extend from the display area AA to a portion of the non-display area NA.

In the light emitting display device of the present disclosure, each of the layers of the organic stack OS may be formed using an open mask (not shown) that completely opens the display area of the substrate 100.

The phosphorescent emission layers 140 (141, 142 and 143) of the second stack S2 or PS in the organic stack OS occupy the entire region of the display area AA and extend to a portion of the non-display area NA. The reason for this is that an open mask (not shown) has therein an open region (corresponding to the shape of 140) in the state of further securing a margin in all directions so as to completely cover the display area AA in consideration of the margin required for alignment of the open mask.

However, when the substrate 100 is in a deposition chamber, the central region and the edge region of the substrate 100 have different thermal gradient characteristics from each other depending on the position of a heat source. The temperature at the edge region is lower than the temperature at the central region, and accordingly an entropy difference occurs between portions of the deposition surface of the substrate 100. Generally, a portion having relatively low entropy is in a relatively stable state, and an organic material is deposited thereon to a large thickness. The edge region has lower entropy than the central region, and accordingly, an organic layer may be deposited on the edge region to a larger thickness than the central region.

In particular, when the third emission layer 143, which is the last deposition layer of the phosphorescent emission layers that perform optical functions in the second stack, is formed, the thermal difference between regions, which was established during the formation of the previous organic layers, is intensified. Accordingly, as shown in FIG. 7, the third emission layer has a thickness difference between the edge region and the central region of the display area AA. Specifically, the third emission layer is deposited on the edge region to a larger thickness than the central region. Because an entropy difference is present between regions in the deposition surface and the third emission layer is deposited on the edge region to a relatively large thickness, for example, if the phosphorescent emission layers are formed to have the same thickness as each other, the thickness difference between the central region and the edge region of the third emission layer increases, so the edge region and the central region have different color shift properties from each other.

That is, the light emitting display device of the present disclosure eliminates abnormal color inversion in the first to third emission layers of the phosphorescent emission unit 140 when driven at a low current density. In addition, the thickness of the third emission layer is reduced in the total thickness of the phosphorescent emission unit in order to minimize the influence of the thickness difference of the third emission layer taking into consideration the fact that the third emission layer has a thickness difference between the edge region and the central region thereof because the third emission layer is the last deposition layer of the phosphorescent emission unit.

In this case, referring to FIG. 7, the difference between the thickness of the third emission layer in the edge region in the display area and the thickness of the third emission layer in the central region in the display area is 8.3% or less of the thickness of the third emission layer in the edge region in the display area.

Meanwhile, although the third emission layer 143 is also formed on a portion of the non-display area NA, the thickness of the third emission layer 143 stacked on the non-display area NA does not affect the display.

The light emitting display device of the present disclosure is capable of eliminating color abnormality in the edge region merely by forming the first to third emission layers to have different respective thicknesses without changing the number of masks or the shapes of masks in the deposition process.

Hereinafter, the light emitting display device of the present disclosure will be described in connection with the configurations of the white light emitting device described above, thin-film transistors, and color filters.

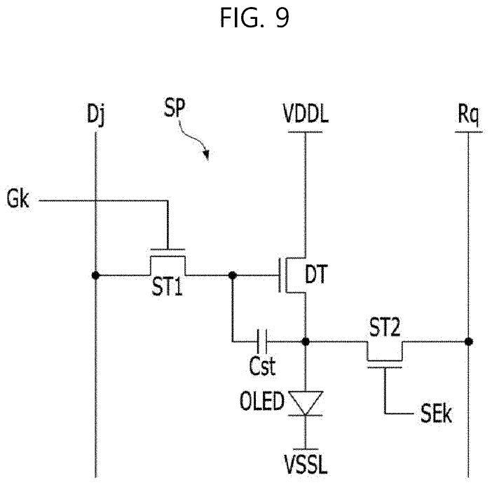

FIG. 8 is a cross-sectional view showing a light emitting display device according to the present disclosure, and FIG. 9 is a circuit diagram of a subpixel according to an example of the light emitting display device of the present disclosure.

As shown in FIG. 8, a light emitting display device 1000 of the present disclosure includes an organic stack OS provided between a first electrode 110 and a second electrode 120 (shown as 200 in FIG. 1), and the organic stack OS includes at least one blue emission stack S1 or BS1/BS2 and a phosphorescent emission stack S2 or PS in which multiple phosphorescent emission layers are stacked (refer to FIG. 1 or 2). A charge generation layer is provided between the blue emission stack and the phosphorescent emission stack. In addition, a hole-transport-related common layer and an electron-transport-related common layer are respectively provided under and on a blue emission layer B EML or B EML1/B EML2 of the blue emission stack S1 or BS1/BS2. The phosphorescent emission stack includes a phosphorescent emission unit 140. The phosphorescent emission unit 140 includes first to third emission layers 141, 142 and 143, which emit lights, the wavelengths of which are gradually shortened from the first emission layer 141 to the third emission layer 143. A hole-transport-related common layer and an electron-transport-related common layer are respectively provided under and on the phosphorescent emission unit 140.

Each subpixel emits white light through the organic stack OS2 provided between the first electrode 110 and the second electrode 120. Color filters 109R, 109G and 109B are provided at emission sides of respective subpixels in order to emit light of different colors.

In the illustrated example, a thin-film transistor array is provided at the emission side. The light from the first electrode 110 passes through the substrate 100 via the color filters 109R, 109G and 109B.

The display device of the present disclosure may include a substrate 100, which has a plurality of subpixels R_SP, G_SP, B_SP and W_SP, a white light emitting device OLED (refer to FIGS. 1 and 2), which is commonly provided in the subpixels R_SP, G_SP, B_SP and W_SP of the substrate 100, a thin-film transistor TFT, which is provided in each of the subpixels and is connected to the first electrode 110 of the white light emitting device OLED, and color filters 109R, 109G and 109B, which are provided under the first electrode 110 of at least one of the subpixels.

Although the display device is illustrated as including the white subpixel W_SP, the aspect is not limited thereto. The white subpixel W_SP may be omitted, and only the red, green and blue subpixels R_SP, G_SP and B_SP may be included. In some cases, the red, green and blue subpixels may be replaced by a cyan subpixel, a magenta subpixel, and a yellow subpixel, which are capable of expressing white in combination.

The thin-film transistor TFT includes, for example, a gate electrode 102, a semiconductor layer 104, a source electrode 106a, which is connected to one side of the semiconductor layer 104, and a drain electrode 106b, which is connected to the opposite side of the semiconductor layer 104.

A gate insulation film 103 is provided between the gate electrode 102 and the semiconductor layer 104.

The semiconductor layer 104 may be formed of a material selected from the group consisting of amorphous silicon, polycrystalline silicon, an oxide semiconductor, and combinations thereof. For example, when the semiconductor layer 104 is formed of an oxide semiconductor, a channel protection layer 105 may be further provided so as to be in direct contact with the upper surface of the semiconductor layer 104 in order to prevent damage to a channel portion of the semiconductor layer 104.

In addition, the drain electrode 106b of the thin-film transistor TFT may be connected to the first electrode 110 in the region of a contact hole CT, which is formed in first and second protective films 107 and 108.

The first protective film 107 is provided to primarily protect the thin-film transistor TFT. The color filters 109R, 109G and 109B may be provided on the first protective film 107.

When the plurality of subpixels SP includes a red subpixel R_SP, a green subpixel G_SP, a blue subpixel B_SP, and a white subpixel W_SP, each of the first to third color filters 109R, 109G and 109B is provided in a corresponding one of the subpixels other than the white subpixel W_SP so as to transmit white light, having passed through the first electrode 110, for each wavelength. The second protective film 108 is formed under the first electrode 110 so as to cover the first to third color filters 109R, 109G and 109B. The first electrode 110 is formed on the surface of the second protective film 108 except for the contact hole CT.

Here, the white light emitting device OLED includes the organic stack OS between the first electrode 110, which is transparent, and the second electrode 120, which is disposed opposite the first electrode 110 and is reflective, and emits light through the first electrode 110.

Here, reference numeral 119 represents a bank, and “BH” between the banks represents a bank hole. Light emission is performed in a region that is open through the bank hole. The bank hole defines an emission portion of each subpixel.

The display device shown in FIG. 8 is a bottom emission-type display device. However, the present disclosure is not limited to a bottom emission-type display device. The display device of the present disclosure may be implemented as a top emission-type display device by changing the structure shown in FIG. 8 such that the color filters are located on the second electrode 120, such that reflective metal is included in the first electrode 110, and such that the second electrode 120 is formed as a transparent electrode or is formed of semi-transmissive metal.

Alternatively, the color filters may be omitted, and both the first electrode 110 and the second electrode 120 may be formed as transparent electrodes, thereby implementing a transparent organic light emitting device.

As shown in FIG. 9, each of the subpixels SP may include a white light emitting device OLED, a driving transistor DT, a plurality of switching transistors, and a capacitor Cst. The plurality of switching transistors may include first and second switching transistors ST1 and ST2. For convenience of description, FIG. 9 illustrates only a pixel P that is connected to a j^{th} data line Dj (j is an integer of two or more), a q^{th} reference voltage line Rq (q being an integer of two or higher), a k^{th} gate line Gk (k is an integer of two or more), and a k^{th} initialization line SEk.

The white light emitting device OLED emits light with a current supplied through the driving transistor DT. A first electrode of the white light emitting device OLED may be connected to a source electrode of the driving transistor DT, and a second electrode of the white light emitting device OLED may be connected to a first power voltage line VSSL through which a first power voltage is supplied. The first power voltage line VSSL may be a low-level voltage line through which a low-level power voltage is supplied.

The driving transistor DT is disposed between the white light emitting device OLED and a second power voltage line VDDL through which a second power voltage is supplied. The driving transistor DT controls the current flowing from the second power voltage line VDDL to the white light emitting device OLED, based on a voltage difference between a gate electrode and a source electrode of the driving transistor DT. The gate electrode of the driving transistor DT may be connected to a first electrode of the first switching transistor ST1, the source electrode of the driving transistor DT may be connected to the second power voltage line VDDL, and a drain electrode of the driving transistor DT may be connected to the first electrode of the white light emitting device OLED. The second power voltage line VDDL may be a high-level voltage line through which a high-level power voltage is supplied.

The first switching transistor ST1 may be turned on by a k^{th} gate signal of the k^{th} gate line Gk and may supply the voltage of the j^{th} data line Dj to the gate electrode of the driving transistor DT. A gate electrode of the first switching transistor ST1 may be connected to the k^{th} gate line Gk, a source electrode of the first switching transistor ST1 may be connected to the gate electrode of the driving transistor DT, and a drain electrode of the first switching transistor ST1 may be connected to the j^{th} data line Dj.

The second switching transistor ST2 may be turned on by a k^{th} initialization signal of the k^{th} initialization line SEk and may connect the q^{th} reference voltage line Rq to the drain electrode of the driving transistor DT. A gate electrode of the second switching transistor ST2 may be connected to the k^{th} initialization line SEk, a first electrode of the second switching transistor ST2 may be connected to the q^{th} reference voltage line Rq, and a second electrode of the second switching transistor ST2 may be connected to the drain electrode of the driving transistor DT.

The capacitor Cst is formed between the gate electrode and the source electrode of the driving transistor DT. The capacitor Cst stores a differential voltage between a gate voltage and a source voltage of the driving transistor DT.

One electrode of the capacitor Cst may be connected to the gate electrode of the driving transistor DT and the source electrode of the first switching transistor ST1, and the other electrode of the capacitor Cst may be connected to the source electrode of the driving transistor DT, the drain electrode of the second switching transistor ST2, and the first electrode of the white light emitting device OLED.

The driving transistor DT, the first switching transistor ST1, and the second switching transistor ST2 of each of the subpixels P may be formed as thin-film transistors. Although it is illustrated in FIG. 3 that the driving transistor DT, the first switching transistor ST1, and the second switching transistor ST2 of each of the subpixels P are formed as N-type semiconductor transistors having N-type semiconductor characteristics, the aspects of the present disclosure are not limited thereto. That is, the driving transistor DT, the first switching transistor ST1, and the second switching transistor ST2 of each of the subpixels P may be formed as P-type semiconductor transistors having P-type semiconductor characteristics.

In the present disclosure, since the phosphorescent emission stack is provided with a red emission layer, a yellowish-green emission layer, and a green emission layer, it is possible to enable rich color representation. Further, the yellowish-green emission layer can be formed to have the largest thickness, whereby it is possible to improve efficiency with color variation when expressing a white color.

A white light emitting device according to one aspect of a present disclosure may comprise a first electrode and a second electrode facing each other on a substrate, a first stack disposed between the first electrode and a first charge generation layer, the first stack to emit a first light and a second stack disposed between the first charge generation layer and the second electrode, the second stack comprising first to third emission layers stacked one on another. The first to third emission layers may emit lights such that wavelengths of the lights are gradually shortened in a direction moving away from the first stack. The third emission layer may have a thickness smaller than a thickness of the first emission layer or a thickness of the second emission layer.

Each of the first to third emission layers may be a phosphorescent emission layer. A total thickness of the first to third emission layers may be 350 Å to 450 Å. And the thickness of the third emission layer may be 20% to 30% of the total thickness of the first to third emission layers.

The thickness of the third emission layer at an edge region of the substrate may be larger than the thickness of the third emission layer at a central region of the substrate.

The thickness of the first emission layer may be 29.5% to 34.1% of the total thickness of the first to third emission layers.

The first emission layer may emit a second light having an emission peak within a range from 590 nm to 650 nm. The second emission layer may emit a third light having an emission peak within a range from 540 nm to 590 nm. The third emission layer may emit a fourth light having an emission peak within a range from 510 nm to 560 nm. The fourth light may have a wavelength longer than a wavelength of the first light.

The first light may have an emission peak within a range from 430 nm to 490 nm. And the first stack may comprise a fourth emission layer to emit the first light.

The white light emitting device may further comprise a second charge generation layer and a third stack provided on the second stack, the third stack comprising a fifth emission layer to emit the first light.

The thickness of the first emission layer may be 65% to 75% of the thickness of the second emission layer. The thickness of the third emission layer may be 45% to 55% of the thickness of the second emission layer.

The first emission layer may be a red emission layer, the second emission layer may be a yellowish-green emission layer, and the third emission layer may be a green emission layer. The thickness of the first emission layer may be 65% to 75% of the thickness of the second emission layer. The thickness of the third emission layer may be 45% to 55% of the thickness of the second emission layer.

A light emitting display device according to one aspect of a present disclosure may comprise a substrate comprising a plurality of subpixels, a first electrode at each of the plurality of subpixels on the substrate, a second electrode provided over the plurality of subpixels to be opposite the first electrode, a first stack between the first electrode and a first charge generation layer over the plurality of subpixels, the first stack being to emit a first light and a second stack between the first charge generation layer and the second electrode over the plurality of subpixels, the second stack comprising first to third emission layers stacked one on another. The first to third emission layers may emit lights such that wavelengths of the lights are gradually shortened in a direction moving away from the first stack. And the third emission layer may have a thickness smaller than a thickness of the first emission layer or a thickness of the second emission layer.

Each of the first to third emission layers may be a phosphorescent emission layer. A total thickness of the first to third emission layers may be 350 Å to 450 Å. The thickness of the third emission layer may be 20% to 30% of the total thickness of the first to third emission layers.

The thickness of the third emission layer in subpixels located at an edge region of the substrate may be larger than the thickness of the third emission layer in subpixels located at a central region of the substrate.

The thickness of the first emission layer may be 29.5% to 34.1% of the total thickness of the first to third emission layers.

The first emission layer may emit a second light having an emission peak within a range from 590 nm to 650 nm. The second emission layer may emit a third light having an emission peak within a range from 540 nm to 590 nm. The third emission layer may emit a fourth light having an emission peak within a range from 510 nm to 560 nm. And the fourth light may have a wavelength longer than a wavelength of the first light.

The first light may have an emission peak within a range from 430 nm to 490 nm. The first stack may comprise a fourth emission layer to emit the first light.

The light emitting display device may further comprise a second charge generation layer and a third stack provided on the second stack, the third stack comprising a fifth emission layer to emit the first light.

The light emitting display device may further comprise a color filter layer and a thin-film transistor between the substrate and the first electrode, the thin-film transistor being connected to the first electrode.

The thickness of the first emission layer may be 65% to 75% of the thickness of the second emission layer. The thickness of the third emission layer may be 45% to 55% of the thickness of the second emission layer.

The first emission layer may be a red emission layer, the second emission layer may be a yellowish-green emission layer, and the third emission layer may be a green emission layer. The thickness of the first emission layer may be 65% to 75% of the thickness of the second emission layer, and The thickness of the third emission layer may be 45% to 55% of the thickness of the second emission layer.

As is apparent from the above description, the white light emitting device and the light emitting display device including the same according to the present disclosure have the following effects.

First, since the phosphorescent emission stack is provided with a red emission layer, a yellowish-green emission layer, and a green emission layer, it is possible to enable rich color representation. Further, the yellowish-green emission layer is formed to have the largest thickness, whereby it is possible to improve efficiency with color variation when expressing a white color.

Second, among the stacked emission layers of different colors of the phosphorescent emission stack, the green emission layer is formed to have the smallest thickness. Accordingly, the thickness of the green emission layer is reduced in the total thickness of the phosphorescent emission layers in the phosphorescent emission stack, whereby it is possible to reduce the influence of a thickness difference of the green emission layer on color representation over the display area. As a result, it is possible to prevent the occurrence of color abnormality in the edge region in the display area.

Third, the ratio of the thicknesses of the red and green emission layers to the thickness of the yellowish-green emission layer is appropriately set so that the degree of variation in color coordinates at a low current density and the degree of variation in color coordinates at a high current density are similar to each other in the edge region and the central region in the display area of the substrate, thereby preventing the occurrence of color abnormality when driven at a low current density.

It will be apparent to those skilled in the art that various modifications and variations can be made in the present disclosure without departing from the spirit or scope of the disclosure. Thus, it is intended that the present disclosure covers the modifications and variations of this disclosure provided they come within the scope of the appended claims and their equivalents.

What is claimed is:

1. A white light emitting device comprising:
a first electrode and a second electrode facing each other over a substrate;
a first stack emitting a first light and disposed between the first electrode and a first charge generation layer; and
a second stack including first to third emission layers stacked on one another and disposed between the first charge generation layer and the second electrode,
wherein the first to third emission layers emit lights such that wavelengths of the lights are gradually shortened in a direction moving away from the first stack, and
wherein the third emission layer has a thickness smaller than a thickness of the first emission layer or a thickness of the second emission layer.

2. The white light emitting device according to claim 1, wherein each of the first to third emission layers includes a phosphorescent emission layer,
wherein a total thickness of the first to third emission layers is between 350 Å and 450 Å, and
wherein a thickness of the third emission layer is 20% to 30% of the total thickness of the first to third emission layers.

3. The white light emitting device according to claim 1, wherein the thickness of the third emission layer at an edge region of the substrate is greater than the thickness of the third emission layer at a central region of the substrate.

4. The white light emitting device according to claim 2, wherein the thickness of the first emission layer is 29.5% to 34.1% of the total thickness of the first to third emission layers.

5. The white light emitting device according to claim 1, wherein the first emission layer emits a second light having an emission peak in a range from 590 nm to 650 nm,
wherein the second emission layer emits a third light having an emission peak in a range from 540 nm to 590 nm,
wherein the third emission layer emits a fourth light having an emission peak in a range from 510 nm to 560 nm, and
wherein the fourth light has a wavelength longer than a wavelength of the first light.

6. The white light emitting device according to claim 1, wherein the first light has an emission peak in a range from 430 nm to 490 nm, and
wherein the first stack includes a fourth emission layer emitting the first light.

7. The white light emitting device according to claim 1, further comprising a second charge generation layer and a third stack disposed on the second stack,
wherein the third stack includes a fifth emission layer emitting the first light.

8. The white light emitting device according to claim 1, wherein the thickness of the first emission layer is 65% to 75% of the thickness of the second emission layer, and
wherein the thickness of the third emission layer is 45% to 55% of the thickness of the second emission layer.

9. The white light emitting device according to claim 1, wherein the first emission layer is a red emission layer, the second emission layer is a yellowish-green emission layer, and the third emission layer is a green emission layer,
wherein the thickness of the first emission layer is 65% to 75% of the thickness of the second emission layer, and
wherein the thickness of the third emission layer is 45% to 55% of the thickness of the second emission layer.

10. A light emitting display device comprising:
a substrate comprising a plurality of subpixels;
a first electrode at each of the plurality of subpixels over the substrate;
a second electrode disposed over the plurality of subpixels to be opposite to the first electrode;
a first stack disposed between the first electrode and a first charge generation layer over the plurality of subpixels, the first stack emitting a first light; and
a second stack disposed between the first charge generation layer and the second electrode, the second stack including first to third emission layers stacked on one another,
wherein the first to third emission layers emit lights such that wavelengths of the lights are gradually shortened in a direction moving away from the first stack, and
wherein the third emission layer has a thickness smaller than a thickness of the first emission layer or a thickness of the second emission layer.

11. The light emitting display device according to claim 10, wherein each of the first to third emission layers includes a phosphorescent emission layer,
wherein a total thickness of the first to third emission layers is 350 Å to 450 Å, and
wherein the thickness of the third emission layer is 20% to 30% of the total thickness of the first to third emission layers.

12. The light emitting display device according to claim 10, wherein the thickness of the third emission layer in subpixels located at an edge region of the substrate is greater than the thickness of the third emission layer in subpixels located at a central region of the substrate.

13. The light emitting display device according to claim 11, wherein the thickness of the first emission layer is 29.5% to 34.1% of the total thickness of the first to third emission layers.

14. The light emitting display device according to claim 10, wherein the first emission layer emits a second light having an emission peak in a range from 590 nm to 650 nm,
wherein the second emission layer emits a third light having an emission peak in a range from 540 nm to 590 nm,
wherein the third emission layer emits a fourth light having an emission peak in a range from 510 nm to 560 nm, and
wherein the fourth light has a wavelength longer than a wavelength of the first light.

15. The light emitting display device according to claim 10, wherein the first light has an emission peak in a range from 430 nm to 490 nm, and
wherein the first stack includes a fourth emission layer emitting the first light.

16. The light emitting display device according to claim 10, further comprising a second charge generation layer and a third stack disposed on the second stack,
wherein the third stack includes a fifth emission layer emitting the first light.

17. The light emitting display device according to claim 10, further comprising a color filter layer and a thin-film transistor between the substrate and the first electrode,
wherein the thin-film transistor is connected to the first electrode.

18. The light emitting display device according to claim 10, wherein the thickness of the first emission layer is 65% to 75% of the thickness of the second emission layer, and
wherein the thickness of the third emission layer is 45% to 55% of the thickness of the second emission layer.

19. The light emitting display device according to claim 10, wherein the first emission layer is a red emission layer, the second emission layer is a yellowish-green emission layer, and the third emission layer is a green emission layer,
wherein the thickness of the first emission layer is 65% to 75% of the thickness of the second emission layer, and
wherein the thickness of the third emission layer is 45% to 55% of the thickness of the second emission layer.

20. A white light emitting device comprising:
an anode electrode and a cathode electrode spaced apart from each other;
a first hole-transport-related common layer disposed on the anode electrode;
a blue emission layer including a first blue dopant and disposed on the first hole-transport-related common layer;
a first electron-transport-related common layer disposed on the blue emission layer;
a first charge generation layer disposed on the first electron-transport-related common layer; and
first to third emission layers disposed between the first charge generation layer and the cathode layer,
wherein a thickness of the third emission layer is 20% to 30% of the total thickness of the first to third emission layers, and
wherein the thickness of the third emission layer at an edge region is greater than the thickness of the third emission layer at a central region.

21. The white light emitting device according to claim 20, wherein each of the first to third emission layers includes a phosphorescent emission layer,

22. The white light emitting device according to claim 20, wherein wavelengths of lights emitted from the first to third emission layers are gradually shortened as being away from the blue emission layer.
